(19) United States
(12) Patent Application Publication
(10) Pub. No.: US 2025/0022783 A1
(43) Pub. Date: Jan. 16, 2025

(54) SEMICONDUCTOR MODULE AND MANUFACTURING METHOD THEREFOR

(71) Applicant: FUJI ELECTRIC CO., LTD., Kawasaki-shi (JP)

(72) Inventor: Kousuke KOMATSU, Matsumoto-city (JP)

(73) Assignee: FUJI ELECTRIC CO., LTD., Kawasaki-shi (JP)

(21) Appl. No.: 18/678,008

(22) Filed: May 30, 2024

(30) Foreign Application Priority Data
Jul. 14, 2023 (JP) 2023-115727

(51) Int. Cl. H01L 23/498; H01L 21/48; H01L 23/00; H01L 23/053; H01L 23/31

(52) U.S. Cl. CPC H01L 23/49811; H01L 21/4853; H01L 23/053; H01L 23/3121; H01L 24/48; H01L 2224/48225

(57) ABSTRACT

A semiconductor module includes: a mounting board; a semiconductor chip mounted on the mounting board; a tubular support conductor mounted on the mounting board; a housing part that accommodates the mounting board, the semiconductor chip, and the support conductor; a connection terminal electrically connected to the semiconductor chip, the connection terminal including a first end portion press-fitted into the support conductor and a second end portion protruding from the housing part; and a conductive first joining part located between an inner wall surface of the support conductor and an outer wall surface of the connection terminal, and configured to join between the support conductor and the connection terminal.

### CROSS REFERENCE TO RELATED APPLICATION

This Application is based on, and claims priority from, Japanese Patent Application No. 2023-115727, filed Jul. 14, 2023, the entire content of which is incorporated herein by reference.

### BACKGROUND OF THE INVENTION

### Field of the Invention

The present disclosure relates to a semiconductor module and a manufacturing method therefor.

### Description of Related Art

A semiconductor module having a structure in which connection terminals for electrically connecting a semiconductor chip to an external device protrude from the exterior surface has conventionally been proposed, as disclosed in, for example, Japanese Patent Application Laid-Open Publication No. 2011-165836, Japanese Patent Application Laid-Open Publication No. 2013-125803, Japanese Patent Application Laid-Open Publication No. 2010-027813, Japanese Patent Application Laid-Open Publication No. 2010-129670. For example, Japanese Patent Application Laid-Open Publication No. 2011-165836 discloses a power semiconductor device that includes tubular electrodes fixed to a circuit pattern on which semiconductor elements are mounted, and connection terminals each inserted in the tubular electrode.

An external device such as a wiring substrate is joined to connection terminals. Accordingly, there is a possibility that an external force from the external device may act on the connection terminals, the connection terminals is consequently displaced (and therefore resulting in falling off) with respect to the corresponding tubular electrodes.

### SUMMARY OF THE INVENTION

In view of the above circumstances, one aspect of the present disclosure has an object to decrease the likelihood of displacement of the connection terminals.

In order to solve the above problem, a semiconductor module according to one aspect of the present disclosure includes: a mounting board; a semiconductor chip mounted on the mounting board; a tubular support conductor mounted on the mounting board; a housing part that accommodates the mounting board, the semiconductor chip, and the support conductor; a connection terminal electrically connected to the semiconductor chip, the connection terminal including a first end portion press-fitted into the support conductor and a second end portion protruding from the housing part; and a conductive first joining part located between an inner wall surface of the support conductor and an outer wall surface of the connection terminal, and configured to join between the support conductor and the connection terminal.

A manufacturing method for a semiconductor module according to another aspect of the present disclosure includes: a mounting process of mounting a semiconductor chip and a tubular support conductor on a mounting board; and a joining process of, with a first end portion of a connection terminal press-fitted into the support conductor and a second end portion of the connection terminal protruding from a housing part support conductor, joining between the support conductor and the connection terminal by way of a first joining part between an inner wall surface of the support conductor and an outer wall surface of the connection terminal, in which the housing part accommodates the mounting board, the semiconductor chip, and the support conductor.

### BRIEF DESCRIPTION OF THE DRAWINGS

FIG. 1 is a cross-sectional view of a semiconductor module according to an embodiment;

FIG. 2 is an exploded perspective view of an external terminal;

FIG. 3 is a cross-sectional view of the external terminal;

FIG. 4 is a cross-sectional view of the external terminal;

FIG. 5 is a cross-sectional view of a state of the semiconductor module in use;

FIG. 6 is a flowchart of processes for manufacturing the semiconductor module;

FIG. 7 is an explanatory diagram of a plating process; and

FIG. 8 is a cross-sectional view of a connection terminal according to a modification.

### DESCRIPTION OF THE EMBODIMENTS

Embodiments of the present disclosure are explained with reference to the drawings. The dimensions and scales of respective elements in the drawings may be different from those of actual products in some cases. The embodiments explained below are exemplary modes that are conceivable when implementing the present disclosure. Therefore, the scope of the present disclosure is not limited to the embodiments explained below.

### A: Structure of Semiconductor Module 100

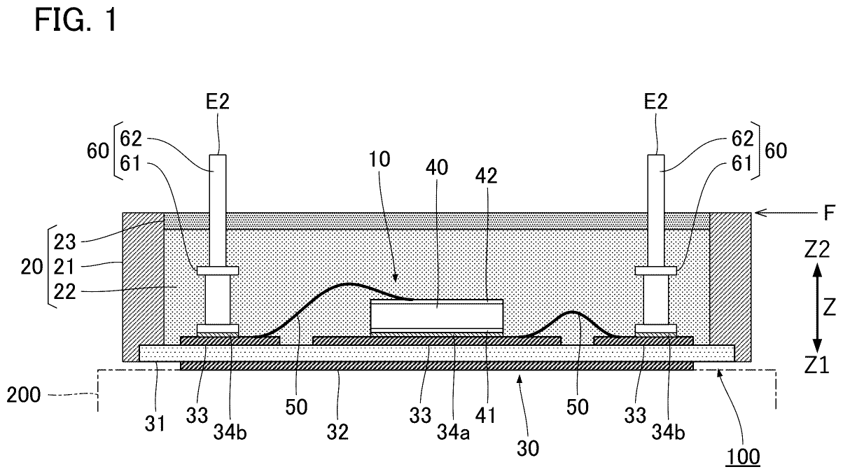

FIG. 1 is a cross-sectional view of a semiconductor module 100 according to one embodiment of the present disclosure. A Z-axis is supposed in the following explanations. One direction along the Z-axis is represented by a Z1 direction and the opposite direction to the Z1 direction is represented by a Z2 direction. While the semiconductor module 100 is installed in a freely selected direction in a state of actual use, the Z1 direction is assumed as a downward direction and the Z2 direction is assumed as an upward direction in the following explanations for the sake of convenience. Therefore, in some cases, a surface facing the Z1 direction of a certain element of the semiconductor module 100 is represented by a “lower surface” and a surface facing the Z2 direction of the element is represented by an “upper surface.” Observing an object by a view along the Z-axis is hereinafter referred to as “plan view.”

The semiconductor module 100 of the present embodiment is, for example, a power semiconductor device constituting a power converter of an inverter circuit, or the like. As illustrated in FIG. 1, the semiconductor module 100 includes a semiconductor unit 10 and a housing part 20. The housing part 20 accommodates the semiconductor unit 10.

The semiconductor unit 10 includes a mounting board 30, a semiconductor chip 40, wires 50, and external terminals 60. Although FIG. 1 illustrates one semiconductor chip 40 for convenience, the semiconductor module 100 in practice includes multiple semiconductor chips 40.

The mounting board 30 is a wiring substrate on which the semiconductor chip 40 is placed. A substrate such as a DCB (Direct Copper Bonding) substrate, an AMB (Active Metal Brazing) substrate, or an IMS (Insulated Metal Substrate) is used as the mounting board 30.

The mounting board 30 is constituted of stacked layers including an insulating substrate 31, a metal layer 32, and conductive patterns 33. The insulating substrate 31 is a rectangular plate member made of an insulating material. The insulating substrate 31 is made of, for example, a ceramic material such as aluminum oxide, aluminum nitride, or silicon nitride, or a resin material such as epoxy resin.

The metal layer 32 is a thin-plate conductor joined to the lower surface of the insulating substrate 31. The metal layer 32 is made of, for example, a metal material of a high thermal conductivity, such as copper or aluminum, and transmits heat generated in the semiconductor chip 40 to a heat radiation mechanism 200. The heat radiation mechanism 200 is a structure joined to the metal layer 32 and is made of, for example, a conductive material such as aluminum or copper.

Each of the conductive patterns 33 is a thin plate conductor mounted on the upper surface of the insulating substrate 31. Each of the conductive patterns 33 is made of, for example, a low-resistance conductive material such as copper or a copper alloy.

The semiconductor chip 40 is a power semiconductor element mounted on the mounting board 30 and is used as a switching element that switches between conduction and interruption of a current. The semiconductor chip 40 of the present embodiment is, for example, an RC-IGBT (Reverse Conducting Insulated Gate Bipolar Transistor) including an IGBT and an FWD (Freewheeling Diode). The semiconductor chip 40 is joined to a conductive pattern 33 by a joining part 34a. The joining part 34a is made of, for example, a conductive joining material such as solder or a sintered material.

The semiconductor chip 40 includes a first electrode 41, a second electrode 42, and a control electrode (not illustrated). The first electrode 41 and the second electrode 42 are electrodes to/from which a current to be controlled is input/output. The first electrode 41 is a collector electrode constituting the lower surface of the semiconductor chip 40 and functions also as a cathode electrode of an FWD. The first electrode 41 of the semiconductor chip 40 is joined to the conductive pattern 33 by the joining part 34a. The second electrode 42 is an emitter electrode constituting the upper surface of the semiconductor chip 40 and functions also as an anode electrode of the FWD. The control electrode is a gate electrode to which a control voltage for controlling ON/OFF of the semiconductor chip 40 is applied, and constitutes the upper surface of the semiconductor chip 40 together with the second electrode 42.

Each of wires 50 is a linear conductor that electrically connects elements of the semiconductor unit 10. The wires 50 include a wire 50 interconnecting conductive patterns 33, and a wire 50 connecting a conductive pattern 33 and the semiconductor unit 10.

Each of the external terminals 60 is an external terminal 60 for electrically connecting the semiconductor unit 10 to an external device. Each external terminal 60 is joined to a corresponding conductive pattern 33 by a joining part 34b. The joining part 34b is made of, for example, a conductive joining material such as solder or a sintered material. The joining part 34b is one example of a “second joining part.”

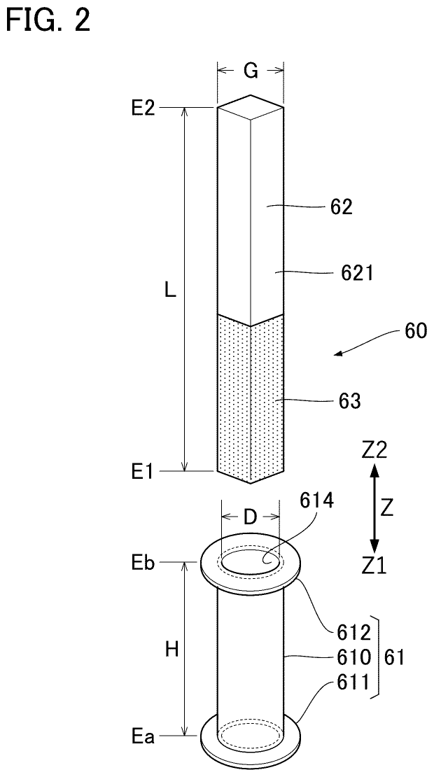

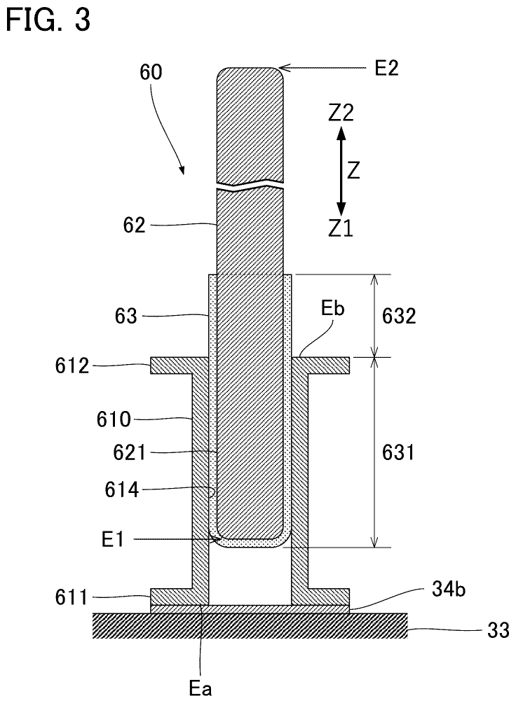

FIG. 2 is an exploded perspective view illustrating a configuration of the external terminal 60. FIG. 3 is a cross-sectional view of the external terminal 60. FIG. 3 shows a cross-section of the external terminal 60 along the Z-axis. As illustrated in FIGS. 1 to 3, each of the external terminals 60 includes a support conductor 61, a connection terminal 62, and a joining part 63.

The support conductor 61 is a cylindrical conductor mounted on the mounting board 30. Specifically, as illustrated in FIGS. 2 and 3, the support conductor 61 is a structure including a tubular portion 610, a first flange portion 611, and a second flange portion 612, that are formed unitarily. The support conductor 61 is made of, for example, a low-resistance conductive material such as elemental copper or a copper alloy. For example, a plating of tin or nickel may be formed on the support conductor 61.

The tubular portion 610 is a cylindrical portion with the central axis along the Z-axis. An inner diameter D of the tubular portion 610 is constant over the entire range in the axis direction. The tubular portion 610 includes a lower end portion Ea and an upper end portion Eb positioned on opposite sides. The lower end portion Ea is an opening end positioned in the Z1 direction. The upper end portion Eb is an opening end positioned in the Z2 direction.

The first flange portion 611 is an annular flange protruding outwardly in the radial direction from the lower end portion Ea of the tubular portion 610. As illustrated in FIG. 3, the first flange portion 611 of the support conductor 61 is joined to the conductive pattern 33 by way of the joining part 34b. The second flange portion 612 is an annular flange protruding outwardly in the radial direction from the upper end portion Eb of the tubular portion 610. One or both of the first flange portion 611 and the second flange portion 612 may or may not be provided.

The connection terminal 62 is an elongated conductor. Specifically, the connection terminal 62 is a square prismatic structure, with a square transverse cross-section. The connection terminal 62 is made of, for example, a low-resistance conductive material such as elemental copper or a copper alloy. For example, a plating of tin or nickel may be formed on the connection terminal 62.

The connection terminal 62 includes a first end portion E1 and a second end portion E2 positioned on opposite sides in the direction of the Z-axis. The first end portion E1 is an end portion in the Z1 direction (that is, the lower end portion). The first end portion E1 is inserted into the support conductor 61. The second end portion E2 is an end portion in the Z2 direction (that is, the upper end portion). A total length L of the connection terminal 62 is greater than a total length H of the support conductor 61.

The connection terminal 62 is inserted into the support conductor 61, thereby being supported by the support conductor 61. As illustrated in FIG. 3, the first end portion E1 of the connection terminal 62 is not in contact with the corresponding conductive pattern 33. That is, in a state in which the connection terminal 62 is inserted into the support conductor 61, a space is provided between the first end portion E1 and the conductive pattern 33. The second end portion E2 protrudes in the Z2 direction from the upper end portion Eb of the support conductor 61.

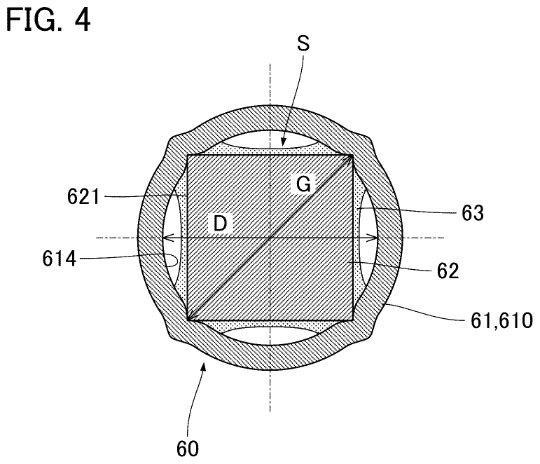

FIG. 4 is a transverse cross-sectional view of the external terminal 60. Specifically, FIG. 4 illustrates a cross-section of the external terminal 60 passing the tubular portion 610 and perpendicular to the Z-axis. As illustrated in FIG. 4, the inner diameter D of the tubular portion 610 of the support conductor 61 is slightly smaller than a diagonal length G of the connection terminal 62. Therefore, a portion of the connection terminal 62 positioned inside the support conductor 61 is in contact with an inner wall surface 614 of the support conductor 61.

That is, the angled parts at four corners in the transverse cross-section of the connection terminal 62 push the inner wall surface 614 of the support conductor 61 outwardly in the radial direction. As illustrated in FIG. 4, portions of the support conductor 61, that are pushed by the angled parts of the connection terminal 62 protrude outwardly in the radial direction.

As will be understood from the above explanations, the first end portion E1 of the connection terminal 62 is press-fitted into the support conductor 61. Consequently, the connection terminal 62 is electrically connected to the semiconductor chip 40 via the support conductor 61 and the corresponding conductive pattern 33. As illustrated in FIG. 4, an outer wall surface 621 of the connection terminal 62 has a region other than the angled parts, that faces the inner wall surface 614 of the support conductor 61 with a space S between the region and the inner wall surface 614.

The joining part 63 is a conductor that joins between the support conductor 61 and the connection terminal 62 to each other and is made of, for example, a conductive joining part 63 such as solder or a sintered material. The joining part 63 is made of, for example, an alloy material including tin as a major component and containing bismuth, copper, nickel, or the like. The joining part 63 is one example of a “first joining part.”

As illustrated in FIG. 2, the joining part 63 covers a portion of the connection terminal 62 including the first end portion E1. The joining part 63 is not formed on the remaining portion of the connection terminal 62 including the second end portion E2. As illustrated in FIG. 3, the joining part 63 includes a first portion 631 and a second portion 632. The second portion 632 of the connection terminal 62 is exposed from the joining part 63.

The first portion 631 is a portion positioned between the inner wall surface 614 of the support conductor 61 and the outer wall surface 621 of the connection terminal 62. That is, as illustrated in FIG. 4, the first portion 631 is filled in the arc-shaped space S between the inner wall surface 614 of the support conductor 61 and the outer wall surface 621 of the connection terminal 62. Specifically, a joining material covering the connection terminal 62 enters the space S by melting, and the joining material in the space S solidifies, forming the joining part 63. The first portion 631 also covers the end face of the first end portion E1.

The second portion 632 is a portion of the joining part 63 positioned in the Z2 direction relative to the upper end portion Eb of the support conductor 61. That is, the second portion 632 is a portion of the joining part 63 exposed from the support conductor 61.

The housing part 20 in FIG. 1 accommodates the semiconductor unit 10 described above. Specifically, the housing part 20 accommodates the mounting board 30, the semiconductor chip 40, the wires 50, and the support conductors 61 of the external terminals 60. The housing part 20 of the present embodiment includes a casing 21, a sealing body 22, and a lid part 23.

The casing 21 is a rectangular frame enclosing the semiconductor unit 10. The mounting board 30 is fixed to the casing 21, for example, with an adhesive. The casing 21 is made of, for example, any of various insulating resins such as PPS (polyphenylene sulfide) resin, PBT (polybutylene terephthalate) resin, PBS (polybutylene succinate) resin, PA (polyamide) resin, or ABS (acrylonitrile-butadiene-styrene) resin.

The sealing body 22 is an insulating material filled in the internal space of the casing 21 and seals the semiconductor unit 10. That is, the sealing body 22 is filled in the internal space having the mounting board 30 as the bottom surface and enclosed by the casing 21.

The sealing body 22 is made of a resin material softer than the casing 21. For example, the sealing body 22 is made of silicone gel. However, the material of the sealing body 22 is not limited to the above example. For example, the sealing body 22 may be made of a resin material such as rubber (for example, silicone rubber) softer than the casing 21. Various types of fillers such as silicon oxide or aluminum oxide may be contained in the sealing body 22.

The lid part 23 is a flat plate member closing the opening of the casing 21. Each of the connection terminals 62 passes through a corresponding through-hole formed on the lid part 23. Therefore, as illustrated in FIG. 1, the second end portion E2 of each of the connection terminals 62 protrudes from the housing part 20. Specifically, the second end portion E2 protrudes in the Z2 direction from an exterior surface F of the housing part 20 in the Z2 direction. The exterior surface F is a surface of the housing part 20, including the top surface of the casing 21 and the upper surface of the lid part 23. The lid part 23 may be constituted integrally with the casing 21.

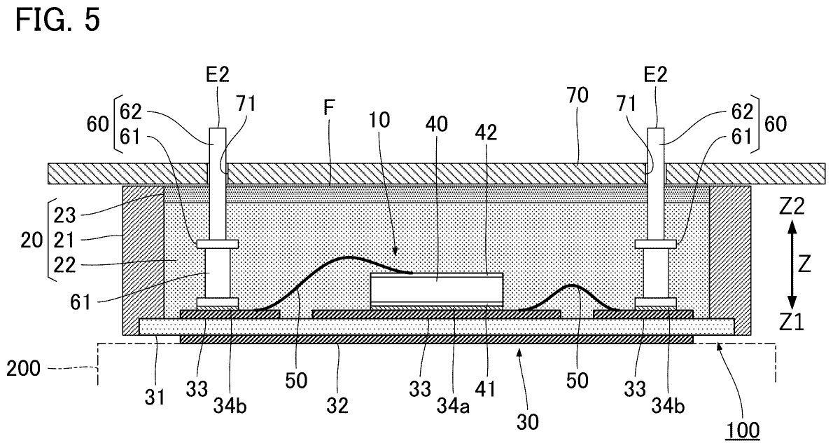

FIG. 5 is a cross-sectional view illustrating a used state of the semiconductor module 100. As illustrated in FIG. 5, a wiring substrate 70 is fixed to the semiconductor module 100 in the used state. The wiring substrate 70 is, for example, a rigid circuit board on which a driving circuit and a power-supply circuit to be used for driving of the semiconductor module 100 are mounted.

Specifically, the wiring substrate 70 is fixed to the semiconductor module 100, facing the exterior surface F of the housing part 20. The wiring substrate 70 is fixed to the casing 21, for example, with fasteners (not illustrated) such as screws or bolts. Each of the connection terminals 62 is inserted into a corresponding through-hole 71 formed on the wiring substrate 70. The second end portion E2 is joined to the wiring substrate 70, for example, with a conductive joining material such as solder or a sintered material.

The connection terminals 62 are joined to the wiring substrate 70 in the manner described above. Therefore, an external force in the Z2 direction may act on the connection terminals 62 from the wiring substrate 70. For example, in the course of replacing the wiring substrate 70, when the installed wiring substrate 70 is moved in the Z2 direction for removal, an external force in the Z2 direction acts also on the connection terminals 62. In the present embodiment, the respective support conductor 61 and the corresponding connection terminal 62 are joined by the joining part 63. Therefore, displacement (and therefore resulting in falling off) of the connection terminals 62 due to action of an external force from the wiring substrate 70 can be suppressed as compared to a configuration in which each of the connection terminals 62 is simply inserted into the corresponding support conductor 61.

The melting point (a solidus temperature Ts and a liquidus temperature Tl) of the joining material used for formation of the joining part 63 is explained next. The solidus temperature Ts of the joining part 63 is a temperature at which the joining material in a solid phase starts melting during temperature increase. The liquidus temperature Tl of the joining part 63 is a temperature at which the joining material is completely melted during temperature increase. In other words, the liquidus temperature Tl is a temperature at which the joining material in the liquid phase starts solidifying during temperature decrease, and the solidus temperature Ts is a temperature at which the joining material is completely solidified during temperature decrease. The liquidus temperature Tl is above the solidus temperature Ts (Tl>Ts).

The solidus temperature Ts of the joining part 63 is above a maximum environmental temperature Tc at which the semiconductor module 100 is used (Ts>Tc). The maximum environmental temperature Tc is the highest temperature in environments in which the semiconductor module 100 is used. For example, the highest value of the operating temperature in the specifications of the semiconductor module 100 corresponds to the maximum environmental temperature Tc. For example, the maximum case temperature in the specifications of the semiconductor module 100 may be the maximum environmental temperature Tc. The maximum case temperature is the highest temperature of the casing 21 conceivable in a normal used state. As described above, according to the configuration of the present embodiment, the solidus temperature Ts of the joining part 63 is above the maximum environmental temperature Tc of the semiconductor module 100. Therefore, the likelihood of the joining part 63 melting in a practical use environment of the semiconductor module 100 can be reduced.

The liquidus temperature Tl of the joining part 63 is below a maximum junction temperature Tjmax of the semiconductor chip 40 (Tl<Tjmax). The maximum junction temperature Tjmax is the highest value of the temperature at which the semiconductor chip 40 appropriately operates.

The liquidus temperature Tl of the joining part 63 is below a solidus temperature Tref of the joining part 34a and the joining part 34b (Tl<Tref). According to the mode described above, the liquidus temperature Tl of the joining part 63 for joining the connection terminal 62 to the support conductor 61 is below the solidus temperature Tref of the joining part 34a and the joining part 34b. Therefore, the connection terminal 62 can be joined to the support conductor 61 by melting and solidifying the joining part 63 while maintaining joining between the semiconductor chip 40 and the mounting board 30 by way of the joining part 34a and joining between the mounting board 30 and the support conductor 61 by way of the joining part 34b.

In the course of melting the joining material for joining each of the connection terminals 62 to the wiring substrate 70, the temperature of the joining part 63 of the external terminal 60 may increase. However, since the heat radiation mechanism 200 has been joined to the metal layer 32 of the mounting board 30 at a stage in which the wiring substrate 70 is mounted, excessive increase in the temperature of the joining part 63 is suppressed by heat radiation from the heat radiation mechanism 200. Therefore, the likelihood of the joining part 63 melting during the installation of the wiring substrate 70 is low. Even if the joining part 63 melts during the installation of the wiring substrate 70, the joining part 63 solidifies again after the installation of the wiring substrate 70 through cooling. Accordingly, the joining between the support conductor 61 and the connection terminal 62 is maintained and melting of the joining part 63 does not cause a significant problem.

### B: Manufacturing Method of Semiconductor Module 100

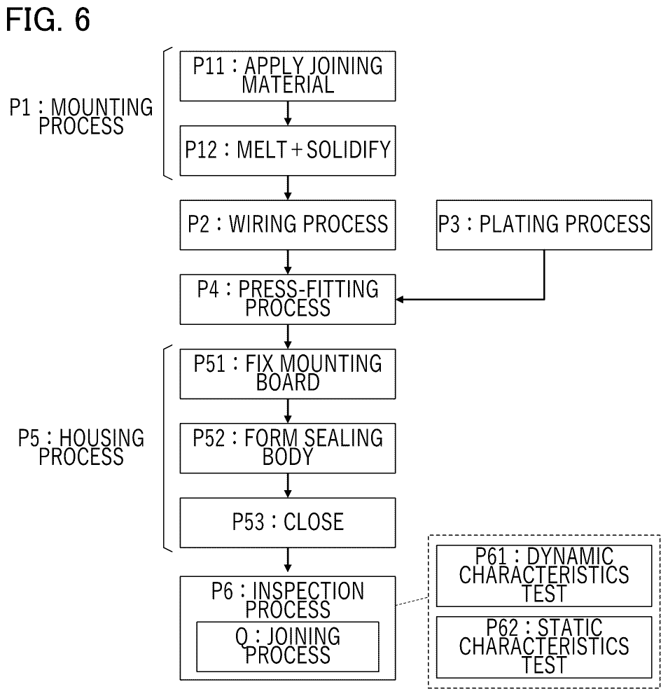

A manufacturing method of the semiconductor module 100 described above is explained. FIG. 6 is an explanatory diagram of processes for manufacturing the semiconductor module 100.

In a mounting process P1, the semiconductor chips 40 and the support conductors 61 are mounted on the mounting board 30. The mounting process P1 includes processes P11 and P12. Specifically, in the process P11, a pasty joining material is applied on the surface of the mounting board 30, and the semiconductor chips 40 and the support conductors 61 are placed on the joining material. In the process P12 after the process P11 is performed, the joining material melts and solidifies to form a joining part 34a and a joining part 34b. That is, each of the semiconductor chips 40 is joined to the mounting board 30 by way of the joining part 34a, and each of the support conductors 61 is joined to the mounting board 30 by way of the corresponding joining part 34b. Wires 50 are formed in a wiring process P2 after the mounting process PI is performed.

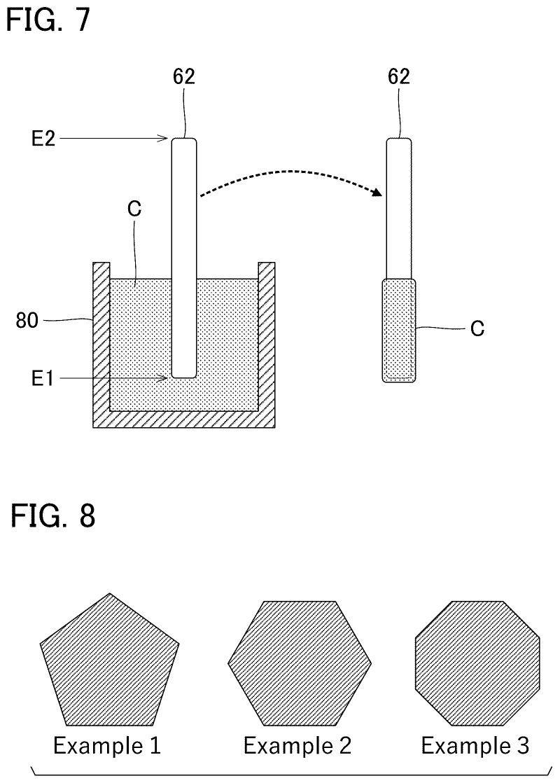

In a plating process P3, a joining material C is provided to the connection terminals 62. For example, as illustrated in FIG. 7, each of the connection terminals 62 is immersed in a plating bath of the joining material C retained in a reservoir 80, so that the joining material C is provided to a portion of the connection terminal 62 including the first end portion E1.

The plating process P3 may be performed anytime irrespective of the mounting process P1 and the wiring process P2. For example, the plating process P3 can be performed either before or after the mounting process P1 and the wiring process P2 are performed, or may be performed in parallel to the mounting process P1 or the wiring process P2.

A press-fitting process P4 is performed after the wiring process P2 and the plating process P3. In the process P4, each of the connection terminals 62 is press-fitted into a corresponding one of the support conductors 61. Specifically, a portion (a portion including the first end portion E1) where the joining material C has been provided in the connection terminal 62 is press-fitted into the support conductor 61. At a stage immediately after the press-fitting process P4, the joining material C becoming the joining part 63 is not melted. That is, the joining part 63 joining between the support conductor 61 and the connection terminal 62 is not yet formed.

A housing process P5 is performed after the press-fitting process P4. In the process P5, the semiconductor unit 10 is accommodated in the housing part 20. The process P5 includes a process P51, a process P52, and a process P53. First, in the process P51, the mounting board 30 is fixed to the casing 21. For example, any of various adhesives may be used to fix the mounting board 30. In the process P52 after the process P51 is performed, a resin material is formed in a space having the mounting board 30 as the bottom surface and enclosed by the casing 21. Specifically, for example, a liquid resin material such as silicone gel is filled in the internal space of the casing 21 and the resin material is cured by heating to form the sealing body 22.

In the process P53 after the process P52 is performed, the opening of the casing 21 is closed by the lid part 23. Each of the connection terminals 62 is inserted into a corresponding one of the through-holes of the lid part 23. At a stage immediately after the housing process P5 described above, the joining material C is provided on, of the connection terminal 62, a portion inside the inside the housing part 20, and a portion outside the housing part 20 is exposed from the joining material C.

The processes (P1 to P5) described above are an assembly process of the semiconductor module 100. Immediately after the assembly process, the first end portion E1 of each of the connection terminals 62 has been press-fitted into the corresponding support conductor 61, with the second end portion E2 of the connection terminal 62 protruding from the housing part 20 that accommodates the semiconductor unit 10. When assembly of the semiconductor module 100 described above has been performed, an inspection process P6 of the semiconductor module 100 is performed before product shipment. The inspection process P6 is a process (pre-shipment inspection) to evaluate the characteristics of each of the semiconductor chips 40.

The inspection process P6 of the present embodiment includes a dynamic characteristics test P61 and a static characteristics test P62. The dynamic characteristics test P61 is a test to evaluate the characteristics of each of the semiconductor chips 40 while dynamically changing the current supplied to the semiconductor chips 40. The static characteristics test P62 is a test to evaluate the characteristics of each of the semiconductor chips 40 at a time when a predetermined DC current is supplied thereto. For example, the electrical characteristics, the temperature characteristics, and the insulating characteristics of each of the semiconductor chips 40 are tested in the dynamic characteristics test P61 and the static characteristics test P62.

In the inspection process P6, the semiconductor chips 40 are driven with the semiconductor module 100 heated. Specifically, in the inspection process P6, the semiconductor chips 40 are driven with the semiconductor module 100 heated to a temperature close to the maximum junction temperature Tjmax, and it is evaluated whether each of the semiconductor chips 40 operates appropriately.

As described previously, the liquidus temperature Tl of the joining material C for forming the joining part 63 is below the maximum junction temperature Tjmax of the semiconductor chips 40. Therefore, the joining material C is melted by heating of the semiconductor module 100 to a temperature close to the maximum junction temperature

Tjmax in the inspection process P6, and the joining material C solidifies by the semiconductor module 100 being cooled in the course of the inspection process P6. The joining part 63 is formed by melting and solidifying of the joining material C. As previously described above with reference to FIG. 4, the connection terminal 62 is in contact with the inner wall surface 614 of the corresponding support conductor 61. Accordingly, electrical conduction between the support conductor 61 and the connection terminal 62 is maintained even with the joining material C melting in the inspection process P6.

That is, the inspection process P6 of the present embodiment includes a joining process Q to form the joining part 63 by melting and solidifying of the joining material C. The joining process Q is a process to join each of the support conductors 61 to the corresponding connection terminal 62 by the joining part 63 between the inner wall surface 614 of the support conductor 61 and the outer wall surface 621 of the connection terminal 62. The joining process Q of the present embodiment is a process to melt and solidify the joining material C by heating of the semiconductor module 100 in the inspection process P6. That is, the joining process Q is realized by heating of the semiconductor module 100 in the inspection process P6. The manufacturing process of the semiconductor module 100 is as described above.

As described above, in the present embodiment, the first end portion E1 on which the joining material C becoming the joining part 63 has been formed is press-fitted into the support conductor 61. Therefore, for example, as compared to a mode in which the joining material C is provided after the first end portion E1 has been press-fitted into the support conductor 61, the joining part 63 can be more easily provided between the inner wall surface 614 of the support conductor 61 and the outer wall surface 621 of the connection terminal 62. However, the joining material C may be injected between the support conductor 61 and the connection terminal 62 after the first end portion E1 is press-fitted into the support conductor 61.

In a mode (hereinafter, “comparative example”) in which the joining material C is provided entirely on the connection terminal 62 including the first end portion E1 and the second end portion E2, there is a possibility that local protrusions (lumps) may be formed due to solidification of the joining material C near the second end portion E2 after melting. If protrusions are formed near the second end portion E2, insertion of the second end portion E2 into, for example, a through-hole 71 of the wiring substrate 70 may be interfered with.

In contrast to the comparative example, the joining material C is provided on, of a connection terminal 62, a portion of inside the housing part 20 and a portion of outside the housing part 20 is exposed from the joining material C in the present embodiment. That is, the joining part 63 is formed on a part of each of the connection terminals 62 including the first end portion E1, and the second end portion E2 is exposed from the joining part 63. According to the mode described above, protrusions caused by melting of the joining material C are prevented from being formed near the second end portion E2. Therefore, joining of the second end portion E2 to, for example, the wiring substrate 70 can be easily performed. In a mode in which local protrusions do not cause a significant problem, the joining material C may be formed to cover the entire surface of each of the connection terminals 62 as in the comparative example described above.

In the present embodiment, the joining material C for joining the support conductor 61 to the connection terminal 62 melts due to heating of the semiconductor module 100 in the inspection process P6. That is, the joining process Q is realized by a part of the inspection process P6. Therefore, the manufacturing process of the semiconductor module 100 is simplified as compared to a mode in which a process of melting the joining material C is performed independently from the inspection process P6. Particularly in the present embodiment, since the liquidus temperature Tl of the joining material C is below the maximum junction temperature Tjmax of the semiconductor chips 40, each of the support conductors 61 and the corresponding connection terminal 62 can be joined to each other by melting the joining material C by heating of the semiconductor module 100 to the maximum junction temperature Tjmax.

### C: Modifications

Specific modes of modification applied to the embodiments explained above are exemplified below. Two or more modes freely selected from the following examples may be combined as appropriate so long as they do not conflict.

(1) In the mode described above, the transverse cross-section of each of the connection terminals 62 is square. However, the shape of each of the connection terminals 62 is not limited to the above example. For example, as illustrated as examples 1 to 3 in FIG. 8, an elongated member having a polygonal transverse cross-section may be used as each of the connection terminals 62. Alternatively, an elongated member having a circular transverse cross-section may be used as each of the connection terminals 62.

(2) In the mode described above, the tubular portion 610 of each of the support conductors 61 is cylindrical has been described. However, the shape of each of the support conductors 61 is not limited to the above example. For example, the support conductor 61 in the form of a rectangular tube having a polygonal transverse cross-section may be used. That is, the support conductor 61 is comprehensively represented as a conductive structure formed in a tubular shape into which the connection terminal 62 can be inserted.

(3) In the mode described above, the housing part 20 is constituted of the casing 21, the sealing body 22, and the lid part 23. However, the present disclosure is also applicable to a mode (full mold) in which the housing part 20 is made of a single resin material

In the mode in which the semiconductor unit 10 is sealed by the soft sealing body 22 as in the embodiment described above, the housing part 20 poorly retains the connection terminals 62, and accordingly, the connection terminals 62 are likely to displace due to action of an external force. Therefore, in the embodiment described above in which the housing part 20 includes the casing 21 and the soft sealing body 22, the configuration is particularly effective that can reduce displacement of the connection terminals 62 by joining between the connection terminals 62 and the support conductor 61 using the joining part 63.

(4) In the plating process P3 of the mode described above, the method of immersing the connection terminals 62 in the plating bath of the joining material C retained in the reservoir 80 has been described. However, the method of providing the joining material C to the connection terminals 62 is not limited to the above example. For example, the connection terminals 62 may be immersed in a tank in which the joining material C has been melted.

(5) In the mode described above, the inspection process P6 includes the joining process Q. However, the joining process Q to join the support conductor 61 to the connection terminal 62 by the joining part 63 may be performed separately from the inspection process P6. For example, the joining part 63 may be formed by melting and solidifying the joining material C between the press-fitting process P4 and the housing process P5. For example, in the process P52 to form the sealing body 22 in the housing process P5, the sealing body 22 is cured by heating the semiconductor module 100. The joining part 63 may be formed by melting the joining material C by the heating in the process P52, and solidifying the joining material C by cooling after the melting.

(6) In the mode described above, the housing process P5 is performed after the press-fitting process P4 is performed. However, the press-fitting process P4 may be performed after the housing process P5 is performed. For example, in a mode in which the upper end portion Eb of each of the support conductors 61 is open on the exterior surface F of the housing part 20, each of the connection terminals 62 may be inserted into the corresponding support conductor 61 after formation of the housing part 20.

(7) In the above modes, the semiconductor chips 40 are RC-IGBTs. However, the form of the semiconductor chips 40 is not limited to the above example. For example, various electronic elements such as an IGBT or an SBD (Schottky Barrier Diode) may be used as the semiconductor chips 40. Alternatively, a MOSFET (Metal-Oxide-Semiconductor Field-Effect Transistor) having a semiconductor layer made of silicon (Si) or silicon carbide (SiC) may be used as a semiconductor chip 40. In a mode in which the semiconductor chip 40 is constituted of a MOSFET, the first electrode 41 is a drain electrode and the second electrode 42 is a source electrode.

(8) The description “nth” (n is a natural number) in the present application is used only as a formal and expedient sign (label) to distinguish among elements in the descriptions and does not have any substantive meaning. Therefore, there is no room for the positions, the manufacturing order, and the like of the elements to be interpreted in a limited manner on the basis of the description “nth.”

### D: Appendix

For example, the following configurations are acquired from the embodiments described above.

A semiconductor module according to one aspect (Aspect 1) of the present disclosure includes a mounting board; a semiconductor chip mounted on the mounting board; a tubular support conductor mounted on the mounting board; a housing part that accommodates the mounting board, the semiconductor chip, and the support conductor; a connection terminal electrically connected to the semiconductor chip, the connection terminal including a first end portion press-fitted into the support conductor and a second end portion protruding from the housing part; and a conductive first joining part located between an inner wall surface of the support conductor and an outer wall surface of the connection terminal, and configured to join between the support conductor and the connection terminal. In this aspect, since the support conductor and the connection terminal are joined by the first joining part, displacement (and therefore resulting in falling off) of the connection terminal can be suppressed as compared to a configuration in which a connection terminal is only press-fitted into a support conductor.

In a specific example (Aspect 2) of Aspect 1, a solidus temperature of the first joining part is above a maximum environmental temperature at which the semiconductor module is used. In this aspect, since the solidus temperature of the first joining part is above the maximum environmental temperature of the semiconductor module, the likelihood of melting of the first joining part in a state of actual use of the semiconductor module can be reduced.

In a specific example (Aspect 3) of Aspect 1 or 2, a liquidus temperature of the first joining part is below a maximum junction temperature of the semiconductor chip. In this aspect, since the liquidus temperature of the first joining part is below the maximum junction temperature (the joining part temperature) of the semiconductor chip, it is possible to form the first joining part (that is, to join between the support conductor and the connection terminal) by melting the joining material in a process of heating the semiconductor module to the maximum junction temperature.

In a specific example (Aspect 4) of any one of Aspects 1 to 3, the support conductor is joined to the mounting board by way of a second joining part, and a liquidus temperature of the first joining part is below a solidus temperature of the second joining part. According to this aspect, the liquidus temperature of the first joining part for joining the connection terminal to the support conductor is below the solidus temperature of the second joining part for joining the support conductor to the mounting board.

Therefore, the connection terminal can be joined to the support conductor by the first joining part by melting and solidifying the joining material while maintaining joining of the mounting board to the support conductor by the second joining part.

In a specific example (Aspect 5) of any one of Aspects 1 to 4, the housing part includes: a casing enclosing the mounting board, the semiconductor chip, and the support conductor; and a sealing body filled in an internal space of the casing, and the sealing body is softer than the casing. In a mode in which the mounting board, the semiconductor chip, and the support conductor are sealed by a soft sealing body, retention of the connection terminal by the housing part is poor and the connection terminal is therefore likely to displace, for example, due to action of an external force. Accordingly, in a configuration in which the housing part includes a casing and a soft sealing body, the configuration of the present disclosure is particularly effective in that it can suppress displacement of the connection terminal by joining between the support conductor and the connection terminal using the first joining part.

In a specific example (Aspect 6) of any one of Aspects 1 to 5, the connection terminal includes a part including the first end portion, the first joining part is formed on the part including the first end portion, and the second end portion is exposed from the first joining part. In a mode in which the joining material for forming the first joining part is provided on the entire connection terminal including the first end portion and the second end portion, there is a possibility that local protrusions (lumps) may be formed due to solidification of the joining material near the second end portion after melting. If protrusions are formed near the second end portion, installation of the second end portion on the wiring substrate or the like (for example, insertion of the second end portion into an attachment hole of the wiring substrate) may be interfered with. According to the mode in which the first joining part is formed only at a part of the connection terminal including the first end portion and in which the second end portion is exposed from the first joining part, it is possible to prevent formation of local protrusions near the second end portion due to melting of the joining material that becomes the first joining part. Therefore, for example, installation of the second end portion on the wiring substrate can be easily performed.

A manufacturing method of a semiconductor module according to one aspect (Aspect 7) of the present disclosure includes: a mounting process of mounting a semiconductor chip and a tubular support conductor on a mounting board; and a joining process of, with a first end portion of a connection terminal press-fitted into the support conductor and a second end portion of the connection terminal protruding from a housing part support conductor, joining between the support conductor and the connection terminal by way of a first joining part between an inner wall surface of the support conductor and an outer wall surface of the connection terminal, in which the housing part accommodates the mounting board, the semiconductor chip, and the support conductor. In this mode, since the support conductor and the connection terminal are joined by the first joining part, displacement (and therefore causing falling of) of the connection terminal can be suppressed as compared to a configuration in which the connection terminal is simply press-fitted into the support conductor.

In a specific example (Aspect 8) of Aspect 7, the method further includes a press-fitting process of press-fitting the first end portion into the support conductor before the joining process, in which on the first end portion there has been formed a joining material becoming the first joining part, and in the joining process, the first joining part is formed by melting and solidifying the joining material. In this aspect, the first end portion on which the joining material becoming the first joining part has been formed is press-fitted into the support conductor. Therefore, the first joining part can be more easily provided between the inner wall surface of the support conductor and the outer wall surface of the connection terminal, for example, as compared to a mode in which the joining material is provided after the first end portion is press-fitted into the support conductor.

In a specific example (Aspect 9) of Aspect 7 or 8, the connection terminal includes a portion inside the housing part and a portion outside the housing part, the joining material is provided on the portion inside the housing part, and the portion outside the housing part is exposed from the joining material. In this aspect, the joining material is mounted on a portion of the connection terminal inside the housing part and a portion of the connection terminal outside the housing part is exposed from the joining material. Therefore, it is possible to prevent formation of local protrusions near the second end portion due to melting of the joining material. Therefore, for example, installation of the second end portion on the wiring substrate can be easily performed.

In a specific example (Aspect 10) of any one of Aspects 7 to 9, the method further includes an inspection process of inspecting the semiconductor module in a heated state, in which the joining process comprises a process of melting and solidifying the joining material by heating the semiconductor module in the inspection process. According to this aspect, the joining material for joining the support conductor to the connection terminal is melted by heating of the semiconductor module in the inspection process. That is, joining is realized by a part of the inspection process. Therefore, the manufacturing of a semiconductor module is simplified as compared to a mode in which melting the joining material is performed independently from the inspection process.

### DESCRIPTION OF REFERENCE SIGNS

100 . . . semiconductor module, 200 . . . heat radiation mechanism, 10 . . . semiconductor unit, 20 . . . housing part, 21 . . . casing, 22 . . . sealing body, 23 . . . lid part, 30 . . . mounting board, 31 . . . insulating substrate, 32 . . . metal layer, 33 . . . conductive pattern, 40 . . . semiconductor chip, 41 . . . first electrode, 42 . . . second electrode, 50 . . . wire, 60 . . . external terminal, 61 . . . support conductor, 610 . . . tubular portion, 611 . . . first flange portion, 612 . . . second flange portion, 614 . . . inner wall surface, 62 . . . connection terminal, 621 . . . outer wall surface, 63 . . . joining part, 631 . . . first portion, 632 . . . second portion.

What is claimed is:

1. A semiconductor module comprising:
a mounting board;
a semiconductor chip mounted on the mounting board;
a tubular support conductor mounted on the mounting board;
a housing part that accommodates the mounting board, the semiconductor chip, and the support conductor;
a connection terminal electrically connected to the semiconductor chip, the connection terminal including a first end portion press-fitted into the support conductor and a second end portion protruding from the housing part; and
a conductive first joining part located between an inner wall surface of the support conductor and an outer wall surface of the connection terminal, and configured to join between the support conductor and the connection terminal.

2. The semiconductor module according to claim 1, wherein a solidus temperature of the first joining part is above a maximum environmental temperature at which the semiconductor module is used.

3. The semiconductor module according to claim 1, wherein a liquidus temperature of the first joining part is below a maximum junction temperature of the semiconductor chip.

4. The semiconductor module according to claim 1, wherein
the support conductor is joined to the mounting board by way of a second joining part, and
a liquidus temperature of the first joining part is below a solidus temperature of the second joining part.

5. The semiconductor module according to claim 1, wherein the housing part includes:
a casing enclosing the mounting board, the semiconductor chip, and the support conductor; and
a sealing body filled in an internal space of the casing, and the sealing body is softer than the casing.

6. The semiconductor module according to claim 1, wherein
the connection terminal includes a part including the first end portion,
the first joining part is formed on the part including the first end portion, and
the second end portion is exposed from the first joining part.

7. A manufacturing method of a semiconductor module, the method comprising:
a mounting process of mounting a semiconductor chip and a tubular support conductor on a mounting board; and
a joining process of, with a first end portion of a connection terminal press-fitted into the support conductor and a second end portion of the connection terminal protruding from a housing part support conductor, joining between the support conductor and the connection terminal by way of a first joining part between an inner wall surface of the support conductor and an outer wall surface of the connection terminal,
wherein the housing part accommodates the mounting board, the semiconductor chip, and the support conductor.

8. The manufacturing method of a semiconductor module according to claim 7, further comprising a press-fitting process of press-fitting the first end portion into the support conductor before the joining process, wherein on the first end portion there has been formed a joining material becoming the first joining part,
wherein in the joining process, the first joining part is formed by melting and solidifying the joining material.

9. The manufacturing method of a semiconductor module according to claim 8, wherein
the connection terminal includes a portion inside the housing part and a portion outside the housing part,
the joining material is provided on the portion inside the housing part, and
the portion outside the housing part is exposed from the joining material.

10. The manufacturing method of a semiconductor module according to claim 8, further comprising an inspection process of inspecting the semiconductor module in a heated state, wherein
the joining process comprises a process of melting and solidifying the joining material by heating the semiconductor module in the inspection process.
